(19) United States
(12) Patent Application Publication
(10) Pub. No.: US 2011/0132646 A1
(43) Pub. Date: Jun. 9, 2011

(54) FLAME RETARDANT EPOXY RESIN COMPOSITION, PREPREG AND LAMINATE THEREOF

(75) Inventors: Sergei V. Levchik, Croton-on-Hudson, NY (US); Fabienne Samyn, Arras (FR)

(73) Assignee: ICL-IP America Inc., Ardsley, NY (US)

(21) Appl. No.: 12/793,353

(22) Filed: Jun. 3, 2010

Related U.S. Application Data
(60) Provisional application No. 61/186,516, filed on Jun. 12, 2009.

(51) Int. Cl. H05K 1/03; C08L 63/02; B29C 65/02

(52) U.S. Cl. 174/258; 525/396; 156/309.9

(57) ABSTRACT

There is provided herein a curable epoxy resin composition comprising at least one brominated epoxy resin, at least one flame retardant curing agent, and at least one curing catalyst.

### CROSS REFERENCE TO RELATED APPLICATIONS

This application claims priority to U.S. Provisional Patent Application No. 61/186,516 filed on Jun. 12, 2009.

### FIELD OF THE INVENTION

This invention relates to flame retardant epoxy resin compositions, in particular curable flame retardant epoxy resin compositions comprising brominated epoxy resin, poly(arylene alkylphosphonate) curing agent, and a curing catalyst. The curable flame retardant epoxy resin compositions shows good set of thermal properties for lead-free soldering.

### DETAILED DESCRIPTION OF THE RELATED ART

Articles prepared from epoxy resin compositions which have improved resistance to elevated temperatures are desirable for many applications. In particular they are desirable for printed wiring board (PWB) applications due to industry trends which include higher circuit densities, increased board thickness, lead free solders, and higher temperature use environments.

There are several commonly used indicators of thermal performance of electrical laminates. One of these is the glass transition temperature (T_{g}) of the cured resin. Another measure is the thermal decomposition temperature (T_{d}) of the cured resin, which is determined using thermogravimetric analysis (TGA). A third indicator is known as “t₂₈₈”, which is the time required for a laminate to begin to delaminate when heated at 288° C. A fourth, but related, indicator is solder dip resistance, which is the time required for the laminate to begin to delaminate when it is dipped into molten solder at 288° C.

Recently, industry standards have begun to specify that lead-free solders have to be used to construct electronic devices. The lead-free solders usually melt at higher temperatures than conventional lead-based solders. The use of these solders therefore places greater demands on the thermal stability of the resin phase of the electrical laminate. Conventional resin formulations have not been able to satisfy these added thermal requirements.

Another circumstance that drives the need for better thermal stability is the production of multilayer boards. These are formed by bonding thin pre-processed boards together using one or more prepregs. This operation can be repeated several times. With each repetition, the entire board is subjected to a complete thermal cure cycle. As a result, the higher the layer count, the greater is the thermal impact on the inner layer board.

Therefore, it is desirable to provide a resin that can enable the laminate to exhibit the needed thermal properties. Laminates exhibiting a T_{d} of 330 C or higher are expected to become standard in the industry. The t₂₈₈ value should be at least 5 minutes, and preferably at least 15 minutes, but values of 30 minutes or more are especially desired. The T_{g} should be 130° C. or more, and preferably at least 150° C.

Laminates are generally manufactured by pressing under elevated temperatures various partially cured prepregs and optionally copper sheeting. Prepregs are generally manufactured by impregnating a curable epoxy resin composition into a glass fiber mat, followed by processing at elevated temperatures to promote a partial cure of the epoxy resin in the mat to a “B-stage.” Complete cure of the epoxy resin impregnated in the glass fiber mat typically occurs during the lamination step when two or more of the prepregs are pressed under high pressure and elevated temperatures for a time sufficient to allow the complete cure of the resin when preparing a laminate.

While epoxy resin compositions are known to impart enhanced thermal properties for the manufacture of prepregs and laminates; such epoxy resin compositions are typically more difficult to process, more expensive to formulate, and may suffer from inferior performance capabilities for complex printed circuit board circuitry and for higher fabrication and usage temperatures.

In light of the above, there is a need in the art for epoxy resin compositions for preparing articles having improved thermal properties and for processes to produce such articles. There is also a need in the art for inexpensive resin compositions for achieving enhanced thermal properties and for articles, especially prepregs and laminates, having enhanced thermal properties in order to manage lead-free soldering temperatures and higher in-use thermal exposure requirements.

Standard FR-4 laminates which are normally used in Printed Circuit Boards (PCB's) are made of brominated bisphenol A epoxy resins cured with dicyandiamide. These standard FR-4 laminates have low thermally stability, that is low degradation temperature (T_{d}) and short time to delamination at 288° C. (t₂₈₈). The term “PCB's” can be used interchangeably herein with the expression “printed circuit boards” or “printed wiring boards”.

Improved thermal stability can be achieved when a phenolic or an anhydride hardener is used instead of dicyandiamide in a varnish formulation for making laminates. However, such varnishes have a narrow processing window. Often the resulting laminate from such varnish has a lower glass transition temperature (Tg), and a lower adhesion to copper foil. The laminates are also more brittle.

In spite of recent improvements made to resin compositions and processes for making electrical laminates, none of the known composition or processes disclose a resin composition useful for making a laminate with a good balance of laminate properties and thermal stability, such as high T_{g}, good toughness, and good adhesion to copper foil.

It would be desirable to provide a curable epoxy resin composition with excellent well-balanced properties for use as a material for making a laminate such that the laminate has excellent well-balanced laminate properties. It would also be desirable to achieve a laminate having high thermal stability with high T_{g}, good adhesion to copper foil and very good flame retardant properties.

It is an object of the present invention is to provide curable flame retardant epoxy resin compositions for use in production of epoxy prepregs and epoxy laminates and in the manufacture of printed-wiring boards and multilayer printed-wiring boards, which possess high thermal stability and good flame retardant properties. Furthermore, it would be advantageous if the laminate showed good adhesion to the copper and high moisture resistance.

### SUMMARY OF THE INVENTION

The present invention provides a curable epoxy resin composition comprising at least one curable brominated epoxy resin, at least one flame retardant curing agent, such as polyarylene alkylphosphonate curing agent, and at least one curing catalyst. The present invention relates to printed wiring boards, e.g., printed wiring boards for electronic applications.

### DESCRIPTION OF THE PREFERRED EMBODIMENTS

The curable flame retardant epoxy resin composition of the present invention comprises, as one essential component, at least one brominated epoxy resin. Brominated epoxy resins are compounds containing at least one vicinal epoxy group and at least one bromine. Examples of brominated epoxy resins useful in the present invention include diglycidyl ether of tetrabromobisphenol A and derivatives thereof.

The brominated epoxy resin is present in an amount that ranges from about 50 to about 90 percent by weight of the total weight of the composition. More preferably, the brominated epoxy resin is present in an amount that ranges from about 65 to about 90 percent by weight of the total weight of the composition.

The brominated epoxy resin may be used alone or optionally in combination with one or more non-halogen-containing epoxy resins.

The non-halogen-containing epoxy resin utilized in the composition of the present invention may be, for example, an epoxy resin or a combination of epoxy resins prepared from an epihalohydrin and a phenol or a phenol type compound, prepared from an epihalohydrin and an amine, prepared from an epihalohydrin and a carboxylic acid, or prepared from the oxidation of unsaturated compounds.

The non-halogen-containing epoxy resin preferably includes those resins produced from an epihalohydrin and resorcinol, catechol, hydroquinone, biphenol, bisphenol A, bisphenol F, bisphenol K, phenol-formaldehyde novolac resins, alkyl substituted phenol-formaldehyde resins, phenol-hydroxybenzaldehyde resins, cresol-hydroxybenzaldehyde resins, dicyclopentadiene-phenol resins, dicyclopentadiene-substituted phenol resins, tetramethylbiphenol, tetramethyltribromobiphenol, or combinations thereof.

Examples of useful non-halogen-containing epoxy resin are oligomeric and polymeric diglycidyl ether of bisphenol A, oligomeric and polymeric diglycidyl ether of tetrabromobisphenol A, oligomeric and polymeric diglycidyl ether of bisphenol A and tetrabromobisphenol A, epoxydized phenol Novolac, epoxydized bisphenol A Novolac, epoxidized cresol novolac, oxazolidone-modified epoxy resins and mixtures thereof.

The ratio of brominated epoxy resin to non-halogenated epoxy resin is preferably chosen to provide flame retardancy to the cured resin and may vary greatly depending on the desired properties and end-use applications and as such can be adjusted accordingly by those skilled in the art. The weight amount of brominated epoxy resin which may be present may vary depending upon the particular chemical structure of the brominated epoxy resin which is used (due to the bromine content), as is known in the art. In one non-limiting embodiment the bromine content in the final formulation is from about 10% to about 30% and preferably from about 15% to about 25% based on the total weight of the epoxy curable composition herein.

The polyarylene alkylphosphonate curing agent is present at from about 5% to about 30%, by weight of the total weight of the composition, preferably from about 5% to about 20%, by weight. This flame retardant curing agent, as more fully described in PCT International Patent Publication No. WO 03/029258, is an oligomeric phosphonate comprising the repeating unit —OP(O)(R)—O-Arylene- where R can be a linear or branched alkyl containing up to about 8 carbon atoms, preferably up to about 6 carbon atoms, and which curing agent has a phosphorus content of greater than about 12%, by weight based on the weight of the curing agent. The phosphonate species in the composition comprise those. containing —OH end groups as well, possibly, those not containing —OH end groups. The individual phosphonate species that contain —OH end groups can be monohydroxy or dihydroxy substituted. The concentration of phosphonate species in the composition that contain hydroxyl end groups will range from about 20% to about 100%, based upon the total number of termination ends (“chain ends”) that potentially could hold such end groups, preferably from about 50% to about 100%. The end groups can be attached to the Arylene moiety or to the phosphorous moiety. The preferred R group is methyl, but can be any lower alkyl. In one embodiment, the polyarylene alkylphosphonate curing agent is poly(m-phenyl methylphosphonate). WO 03/029258 is incorporated by reference herein in its entirety.

By “Arylene” is meant any radical of a dihydric phenol. The dihydric phenol preferably should have its two hydroxyl groups in non-adjacent positions. Examples include the resorcinols; hydroquinones; and bisphenols, such as bisphenol A, bisphenol F, and 4,4′-biphenol, phenolphthalein, 4,4′-thiodiphenol, or 4,4′-sulfonyldiphenol. The Arylene group can be 1,3-phenylene, 1,4-phenylene, or a bisphenol diradical unit, but it is preferably 1,3-phenylene.

In one embodiment the curing catalyst is a tetrahydrocarbyl phosphonium salts. Preferred catalysts are, but not limited to, quaternary phosphonium and ammonium salts. The quaternary phosphonium salts include, for example, tetrabutylphosphonium chloride, tetrabutylphosphonium bromide, tetrabutylphosphonium iodide, tetrabutylphosphonium acetate complex, tetraphenylphosphonium chloride, tetraphenylphosphonium bromide, tetraphenylphosphonium iodide, ethyltriphenylphosphonium chloride, ethyltriphenylphosphonium bromide, ethyltriphenylphosphonium iodide, ethyltriphenylphosphonium acetate complex, ethyltriphenylphosphonium phosphate complex, propyltriphenylphosphonium chloride, propyltriphenylphosphonium bromide, propyltriphenylphosphonium iodide, butyltriphenylphosphonium chloride, butyltriphenylphosphonium bromide, butyltriphenylphosphonium iodide, ethyltri-p-tolylphosphonium acetate/acetic acid complex, ethyltriphenylphosphonium acetate/acetic acid complex or combinations thereof. It will be understood herein that the catalyst can comprise any combination of any of the catalysts described herein.

In another embodiment of the present invention the curing catalyst is a compound containing amine, heterocyclic nitrogen or ammonium. Preferred catalysts are the heterocyclic nitrogen and amine-containing compounds and even more preferred compounds are heterocyclic nitrogen-containing compounds.

Particularly suitable onium or amine compounds useful as catalysts include, for example, ethyltriphenyl phosphonium acetate, ethyltriphenyl phosphonium acetate-acetic acid complex, tetrabutylphosphonium acetate, tetrabutyl-phosphonium acetate-acetic acid complex, ethyltriphenyl phosphonium chloride, ethyl triphenyl phosphonium iodide, tetrabutylphosphonium chloride, tetrabutylphosphonium iodide, tetrabutylphosphonium hydroxide, tetrabutylammonium hydroxide, tetraethylammonium hydroxide, tetramethylammonium hydroxide, N-methylmorpholine, 2-methylimidazole, triethylamine, N,N,N′,N′-tetramethylethylenediamine, ethyltri(2-hydroxyethyl) ammonium hydroxide, ethyltri(2-ethoxyethylammonium hydroxide, triethyl (2-thioethylethyl)ammonium hydroxide, N-methyl-N-methylenemethanaminium acetate, N-methyl-N-methylene-methanaminium acetate-acetic add complex, N-methyl-N-methylenemethanaminium chloride, N-methyl-N-methylenemethanaminium iodide, N-methylpyridinium acetate, N-methylpyridinlum acetate-acetic acid complex, N-methylpyridinium chloride, N-methylpyridinium iodide, 1-ethyl-2,3-dimethylimidazolium acetate, 1-ethyl 1-2,3-dimethylimidazolium acetate-acetic acid complex, 1-ethyl-2,3-dimethylimidazolium chloride, 1-ethyl-2,3-dimethyl-imidazolium iodide, N-methylquinolinium acetate, N-methylquinolinium acetate-acetic acid complex, N-methylquinolinium chloride, N-methylquinolinium iodide, N-methyl-1,3,5-triazinium acetate, N-methyl-1,3,5-triazinium acetate-acetic acid complex, N-methyl-1,3,5-triazinium chloride, N-methyl-1,3,5-triazinium iodide and any combination thereof.

The amine compounds useful as catalysts which can be suitably employed herein include, for example, primary, secondary, tertiary, aliphatic, cycloaliphatic, aromatic or heterocyclic amines.

Preferable non-heterocyclic amines which can be employed herein as catalyst include, those containing suitably from 1 to 60, more suitably from 2 to 27, most suitably from 2 to 18, carbon atoms. Particularly preferable amines include, for example, ethylamine, diethylamine, triethylamine, n-propylamine, di-n-propylamine, tri-n-propylamine, isopropylamine, diisopropylamine, triisopropylamine, butylamine, dibutylamine, tributylamine methyldibutylamine, and combinations thereof.

Among preferred tertiary amines that may be used as catalysts are those mono- or polyamines having an open-chain or cyclic structure which have all of the amine hydrogen replaced by suitable substituents, such as, hydrocarbon radicals, and preferably aliphatic, cycloaliphatic or aromatic radicals. Examples of these amines include, among others, methyl diethanolamine, triethylamine, tributylamine, dimethyl benzylamine, triphenylamine, tricyclohexyl amine, pyridine and quinoline. Preferred amines are the trialkyl, tricycloalkyl and triaryl amines, such as triethylamine, triphenylamine, tri(2,3-dimethylcyclohexyl)amine, and the alky) dialkanolamines, such as methyl diethanolamines and the trialkanolamines such as triethanolamine. Also useful are 1,5-diazabicyclo[4.3.0]non-5-en, 1,4-diazabicydo[2.2.2]octane, and 1,8-diazabicyclo[5.4.0]undec-7-en(1,5-5).

Preferable heterocyclic secondary and tertiary amines or nitrogen-containing compounds which can be employed herein as catalyst include, for example, imidazoles, imidazolidines, imidazolines, oxazoles, pyrroles, thiazoles, pyridines pyrazines, morpholines, pyridaztnes, pyrimidines, pyrrolidines, pyrazoles, qulnoxalines, quinazolines, phthalozines, qui-nolines, purines, indazoles, indoles, Indolazines, phenazlnes, phenarsazines, phenothiazines, pyrrolines, indolines, piperidines, piperazines and combinations thereof.

Examples of imidazoles include, among others, imidazole, benzimidazole and substituted examples. Preferable substituted imidazoles include: 1-methylimidazole; 2-methyl imidazole; 2-ethylimidazole, 2-propylimidazole, 2-butylimidazole, 2-pentylimidazole, 2-hexylimidazole, 2-cyclohexylimidazole, 2-phenylimidazole, 2-nonyl-imidazole, 2-undecylimidazole, 2-heptadecylimidazole, 2-phenyl-4-methylimidazole, 1-benzylimldazole, 1-ethyl-2-methylbenzimidazole, 2-methyl-5,6-benzimidazole, 1-vinylimidazole, 1-allyl-2-methylimidazole, 2-cyanoimidazole, 2-chloroimidazole, 2-bromoimidazole, 1-(2-hydroxypropyl)-2-methylimidazole, 2-phenyl-4,5-dimethylolimidazole, 2-phenyl-4-methyl-5-hydroxymethylimidazole, 2-chloromethylbenzimidazole, 2-hydroxybenzimidazole, 2-ethyl-4-methylimidazole; 2-cyclohexyl-4-methylimidazoles; 4-butyl-5-ethylimidazole; 2-butoxy-4-allylimidazole; 2-carboethyoxy-butylimidazole, 4-methytimidazole; 2-octyl-4-hexylimidazole; 2-methyl-5-ethylimidazole; 2-ethyl-4-(2-ethylamino)imidazole; 2-methyl-4-mercaptoethylimidazole; 2,5-chloro-4-ethylimidazole; and mixtures thereof. Preferred are the alkyl-substituted imidazoles; 2,5-chloro-4-ethylimidazole; and phenyl-substituted imidazoles, and mixtures thereof. Even more preferred are 2-methylimidazole; 2-ethyl-4-methylimidazole; 1,2-dimethylimidazole; 2-phenylimidazole; and 1-methylimidazole.

The amount of catalyst used depends on the molecular weight of the catalyst, the activity of the catalyst and the speed at which the polymerization is intended to proceed. In general, the catalyst is used in an amount of from 0.01 parts per 100 parts of resin (p.h.r.) to about 1.0 p.h.r., more preferably, from about 0.01 p.h.r. to about 0.5 p.h.r. and, most preferably, from about 0.1 p.h.r. to about 0.5 p.h.r. In one embodiment herein it will be understood herein that parts of resin relates to the parts of curable epoxy resin described herein, i.e., the total amount of the curable composition excluding catalyst, (total grams of brominated epoxy+non-brominated epoxy+polyphosphonate=100% and then taking 100grams of this is equal to 100 parts of resin); catalyst is added in above ranges to 100 parts of this total weight amount.

The epoxy resin composition of the present invention can contain optional additives, for example, auxiliary flame retardant additives, and solvents such as methyl ethyl ketone, acetone, toluene, and mixtures thereof, as well as, the following types of materials: fiber and/or cloth reinforcing mats; mineral fillers, such as Al(OH)₃, Mg(OH)₂ or silica; and the like.

In one embodiment herein there is provided an article that contains the curable epoxy resin composition described herein. In one embodiment the article herein can be used in lead free soldering applications and electronic devices, e.g., printed wiring board applications, specifically the article can be a prepreg and/or a laminate. In one specific embodiment there is provided a laminate and/or a prepreg that contains the curable epoxy resin composition described herein. In one other embodiment there is provided herein a printed wiring board, optionally a multilayer printed wiring board, comprising one or more prepreg(s) and/or a laminate (e.g., either uncured, partially cured or completely cured) wherein said prepreg(s) and/or laminate comprise the curable epoxy resin composition described herein. In one embodiment there is provided a printed wiring board comprising a prepreg and/or a laminate wherein said prepreg and/or laminate comprises the curable epoxy resin composition described herein. Partial curing can comprise any level of curing, short of complete cure, and will vary widely depending on the specific materials and conditions of manufacture as well as the desired end-use applications. In a preferred embodiment, the article herein can further comprise a copper foil. In one embodiment the article can comprise a printed wiring board. In one embodiment there is provided an FR-4 laminate which comprises a prepreg and/or laminate of the invention. In a more specific embodiment there is provided a printed circuit board comprising an FR-4 laminate, wherein the FR-4 laminate comprises a prepreg or laminate of the invention.

In one embodiment herein there is provided a process of making a laminate that contains the curable epoxy resin composition herein comprising impregnating the curable epoxy resin composition into a filler material, e.g., a glass fiber mat to form a prepreg, followed by processing the prepreg at elevated temperature and/or pressure to promote partial cure to a B-stage and then laminating two or more of said prepregs to form said laminate. In one embodiment said laminate and/or prepreg can be used in the applications described herein, e.g., printed wiring boards.

There is provided herein a resin composition useful for making a prepreg and/or laminate with a good balance of laminate properties and thermal stability, such as one or more of high T_{g} (i.e. above 130° C.), T_{d} of 330° C. and above, t₂₈₈ of 5 minutes and above, a flame resistance rating of V-0, good toughness, and good adhesion to copper foil. In recent years T_{d} has become one of the most important parameters, because the industry is changing to lead-free solders which melt at higher temperature than traditional tin-lead solders.

In one embodiment herein the epoxy resin composition can be used in other applications, e.g., encapsulants for electronic elements, protective coatings, structural adhesives, structural and/or decorative composite materials in amounts as deemed necessary depending on the particular application.

The present invention is further illustrated by the Examples that follow:

### EXAMPLES

Materials

Brominated Epoxy 1, Tetrabromobisphenol A epoxy, D.E.R. 530 A-80 (80% solution in acetone), brand of Dow Chemical
Brominated Epoxy 2, Tetrabromobisphenol A epoxy, Araldite LZ8001 A-80 (80% solution in acetone), brand of Huntsman
Non-Halogen-Containing Epoxy, (D.E.R) bisphenol A epoxy, D.E.R. 331, brand of Dow

Chemicals

Curing Agent, (PMP) poly(m-phenylene methylphosphonate), Fyrol PMP-M (80% solution in MEK), brand of ICL-IP
Catalyst, (ETPPAc) ethyl triphenyl phosphonium acetate (70% solution in methanol), purchased from Alfa Aesar
Solvent: methylethyl ketone, (MEK), purchased from Fluka
Glass cloth: 7628/50 style, product of BGF Industries
Copper Foil: Gould Electronics Inc., (JTC, 1.0 oz/ft.²)

Preparation of the Varnish

Weighted amount of epoxy resin(s) and Fyrol PMP-M were preheated in separate jars to the temperature of 60°. The resins and Fyrol PMP were poured into a 3 neck round bottom flask equipped with a mechanical stirrer, a thermometer and a heating mantle. Then about 25 p.h.r. of MEK was added at continuous stirring until a clear uniform solution was obtained. The viscosity of solution was adjusted to the range of 700-1000 cPa (@25° C.) by further addition of MEK. The catalyst was added to the varnish last before cooling.

Manufacturing of Prepreg

The glass cloth (10.5×10.5 inch) was manually brushed on the both sides with varnish at room temperature. The glass cloth was placed in a preheated air circulated oven at 180° C. and exposed to the heat for a certain period of time. Prepregs with resin content of about 40-45% were manufactured based on the total amount of curable epoxy resin, composition. The expression resin content as used above is understood to be the percentage that is equal to 100 *(total weight of epoxy resin+brominated epoxy resin)/(total weight of epoxy resin+brominated epoxy resin+polyphosphonate+catalyst).

Resin Flow Measurement

The obtained prepregs were tested for resin flow according to IPC-TM-650 test 2.3.16.2. The desired target of resin flow was in the range from 10 to 15%.

Manufacturing of Laminate

The stack of 8 prepregs with a copper foil in the bottom and on the top was placed between two stainless steel plates. Four sheets of Kraft paper were placed below and above the plates. The entire assembly was placed in a hydraulic press which was linearly heated to 185° C. Pressure of 200 psi was applied at 170° C. Laminates were cured at isothermal (185° C.) heating for 90 minutes followed by postcuring at 215° C. for 15 minutes.

Pressure Cooker Test

The copper was etched from laminates according to IPC-TM-650, test 2.3.7.1. The pressure cooker test (PCT) was performed according to IPC-TM 650, test 2.6.16 with the following modifications: the temperature of solder bath was held at 288° C. instead of 260° C.

Glass Transition Temperature (T_{g})

Glass transition temperature was measured by Differential Scanning Calorimetry (DSC) according to IPC-TM 650, test 2.4.25 or by Dynamical Mechanical Analysis (DMA).

Thermal Stability

Thermal stability of laminates was measured by Thermogravimetric analysis (TGA) at a heating rate of 10° C./minute in inert atmosphere of nitrogen. 5 percent wt. loss was recorded as T_{d}.

Table 1

Table 1 below details the composition of the varnish and the physical properties of resultant prepregs and the physical properties of resultant laminates Table 1.

TABLE 1

| | Example | | | | |
|---|---|---|---|---|---|
| | 1 | 2 | 3 | 4 | 5 |
| | Composition, wt. % | | | | |
| Brominated Epoxy 1 | — | — | — | — | 83 |
| Brominated Epoxy 2 | 83 | 59 | 37 | 18 | — |
| Non-halogen Epoxy | — | 20 | 37 | 53 | — |
| Polyphosphonate curing | 17 | 21 | 26 | 29 | 17 |
| agent | | | | | |
| Catalyst, p.h.r. | 0.4 | 0.4 | 0.4 | 0.4 | 0.2 |
| | B-staging/lamination | | | | |
| Time (s) | 170 | 185 | 220 | 270 | 160 |
| Resin Flow (%) | 14 | 11 | 14 | 11 | 11 |
| Laminate thickness (mm) | 1.4 | 1.5 | 1.5 | 1.4 | 2.0 |
| | Pressure Cooker Test | | | | |
| Pass/Fail 30 mins | N/D | Fail | Fail | Fail | Passed |
| Water Uptake (%) | N/D | 0.50 | 0.45 | 0.32 | 0.20 |
| | UL-94 flammability test | | | | |
| | Pass | Pass | Pass | Pass | Pass |
| Afterflame time (s) | 0 | 0 | 0 | 0 | 0 |
| Time to delamination | N/D | 43 | 53 | 56 | N/D |
| (TMA) (mins) | | | | | |
| | Thermal properties | | | | |
| T_{g} by DMA (° C.) | N/D | N/D | N/D | N/D | 153 |
| T_{g} from DSC (° C.) | 111 | 111 | 110 | 91 | N/D |
| T_{g} (° C.) | 341 | 341 | 343 | 350 | 360 |

1. A curable epoxy resin composition comprising at least one brominated epoxy resin, at least one poly(arylene alkylphosphonate) curing agent, and at least one curing catalyst.

2. The curable epoxy resin composition of claim 1, wherein the poly(arylene alkylphosphonate) curing agent is poly(m-phenylene methylphosphonate).

3. The curable epoxy resin composition of claim 1 wherein the brominated epoxy resin is present in an amount that ranges from about 50 to about 90 percent by weight of the total weight of the curable epoxy resin composition.

4. The curable epoxy resin composition of claim 1 wherein the polyarylene alkylphosphonate is present in an amount that ranges from 5 to about 40 percent by weight of the total weight of the composition.

5. The curable epoxy resin composition of claim 1 wherein the catalyst is phosphonium quaternary salt.

6. The curable epoxy resin composition of claim 1 wherein the catalyst is imidazole or derivatives of imidazole.

7. The curable epoxy resin composition of claim 1 wherein the catalyst is present in an amount from about 0.01 to about 1.0 parts per 100 parts of curable epoxy resin.

8. An article comprising the composition of claim 1.

9. The article of claim 8 wherein said article can be used in lead free soldering applications and electronic devices.

10. The article of claim 8 wherein the article further comprises a copper foil.

11. The article of claim 8 wherein said article is a printed wiring board.

12. A prepreg comprising the composition of claim 1.

13. A laminate comprising the composition of claim 1.

14. A printed wiring board comprising prepreg of claim 12

15. A printed wiring board comprising the laminate of claim 13.

16. A process of making a laminate that contains the curable epoxy resin composition of claim 1 comprising impregnating the curable epoxy resin composition into a filler material, to form a prepreg, followed by processing the prepreg at elevated temperature to promote partial cure to a B-stage and then laminating two or more of said prepregs at elevated pressure and temperature to form a laminate.

17. A printed wiring board made by the process of claim 16.
